(19) United States
(12) Patent Application Publication
(10) Pub. No.: US 2010/0131807 A1
(43) Pub. Date: May 27, 2010

(54) DECODING ALGORITHM FOR QUADRATIC RESIDUE CODES

(75) Inventors: Trieu-Kien TRUONG, Kaohsiung City (TW); Tsung-Ching LIN, Kaohsiung County (TW); Pei-Yu SHIH, Taipei City (TW); Wen-Ku SU, Kaohsiung City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: I-SHOU UNIVERSITY, Kaohsiung County (TW)

(21) Appl. No.: 12/323,504

(22) Filed: Nov. 26, 2008

(51) Int. Cl. H03M 13/15; G06F 11/34; G06F 11/10

(52) U.S. Cl. 714/704; 714/785; 714/E11.033

(57) ABSTRACT

A decoding algorithm for quadratic residue codes applicable to the decoding of all quadratic residue codes is provided. The decoding algorithm employs digital signals to obtain a plurality of known syndromes. These known syndromes are used to calculate a plurality of unknown syndromes. The inverse-free Berlekamp-Massey algorithm is then used to calculate the error polynomial, after which the Chien search algorithm is used to determine the error locations. Adjustments can then be made to the digital signal bits corresponding to the error locations to obtain the correct code.

### BACKGROUND OF THE INVENTION

1. Field of Invention

This invention relates to a decoding algorithm, more particularly a decoding algorithm for decoding quadratic residue code.

2. Related Art

In today's digital era, a wide variety of signals—such as video and audio signals—are digitalized. A few examples of products that use digital signals include digital TV, Bluetooth headphones, DVD players, WAP mobile phone handsets, etc. To ensure that the signals used in digital products can be read properly, enabling the products to present high-definition video and audio even when the signals have been transmitted over long distances, the signals are typically encoded and decoded.

Currently, quadratic residue codes are widely used in digital encoding and decoding in many different fields. In most cases, the decoding of quadratic residue codes involves the use of an algebraic decoding method to eliminate unknown syndromes from among the Newton's identities so as to obtain the error polynomial coefficient, which in turn can be used to obtain the error polynomial. However, as the length of quadratic residue codes increases, it becomes increasingly difficult for the high order equations produced when using an algebraic method to find a solution over a finite field, making it difficult to obtain the error polynomial.

To address the problem of the increasing difficulty in obtaining the error polynomial by algebraic methods as quadratic residue codes grow longer, the inverse-free Berlekamp-Massey algorithm is widely used to calculate the error polynomial. However, there are not enough continuous known syndromes for quadratic residue codes to enter into the inverse-free Berlekamp-Massey algorithm to be able to calculate the correct error polynomial, which in turn would make it possible to obtain the correct coding within the error correction capability of quadratic residue code. Thus it is important to find error polynomial.

### SUMMARY OF THE INVENTION

To solve the problems discussed above, the present invention provides a decoding algorithm applicable to all quadratic residue codes.

The quadratic residue code decoding algorithm of the present invention uses the digital signal to calculate a plurality of known syndromes, and to set the number of errors if error is encountered and the error correction threshold. The known syndromes are then used to calculate a plurality of unknown syndromes. The known syndromes and unknown syndromes are then treated as known, and the inverse-free Berlekamp-Massey algorithm is used to calculate the error polynomial.

A determination is then made as to whether the highest degree of error polynomial matches the number of errors. If it does match the number of errors, then the Chien search algorithm is used to obtain the roots and root number for the error polynomial. If the highest degree does not match the number of errors, then this implies that the error polynomial that has been obtained is incorrect; in this case, a specified value is added to the number of errors and a determination is made as to whether the number of errors exceeds the error-correction threshold. If it is determined that the number of errors does not exceed the error-correction threshold, then a new set of calculations is made to calculate a plurality of unknown syndromes, and the inverse-free Berlekamp-Massey algorithm is again used to determine the error polynomial. If it is determined that the number of errors does exceed the error correction threshold, then the decoding procedure is terminated.

After the Chien search algorithm has been used to obtain the roots and root number for the error polynomial, a determination can be made as to whether the error polynomial roots match the number of errors. If it is determined that the error polynomial roots do not match the number of errors, then a specified value is added to the number of errors and a determination is made as to whether the number of errors now exceeds the error-correction threshold. If it is determined that the error polynomial roots do match the number of errors, then the error locations for the error polynomial are found, and adjustments are then made to the digital signal bits corresponding to the error locations so as to obtain the correct code.

The quadratic residue code decoding algorithm of the present invention is applicable to all quadratic residue codes, and has been shown by computer verification to provide a level of decoding capability that cannot be achieved with conventional quadratic residue code decoding methods.

### BRIEF DESCRIPTION OF THE DRAWINGS

FIG. 1 shows a flow chart for decoding (89,45,17) quadratic residue code using the quadratic residue code decoding algorithm of the present invention.

FIG. 2 shows a flow chart for decoding (71,36,11) quadratic residue code using the quadratic residue code decoding algorithm of the present invention.

FIG. 3 shows a flow chart for decoding (79,40,15) quadratic residue code using the quadratic residue code decoding algorithm of the present invention.

### DETAILED DESCRIPTION OF THE INVENTION

The present invention will be described in more detail below with reference to the embodiments and drawings.

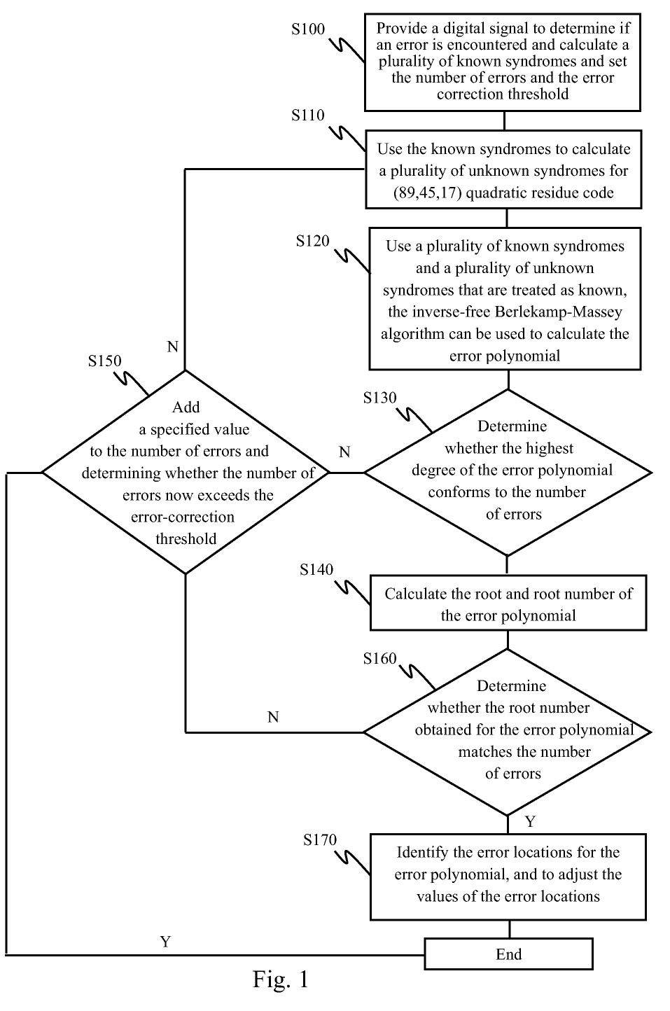

Referring to FIG. 1 which shows a flow chart for decoding (89,45,17) quadratic residue code using the quadratic residue code decoding algorithm of a first embodiment of the present invention, the decoding process comprises the following steps:

A digital signal is provided, and used to calculate a plurality of known syndromes and set the number of errors if error is encountered and the error correction threshold (Step S100). In this step, Equation 1 is used to derive a plurality of known syndromes from the digital signal. It is assumed that the number of errors is v; this value is initially set at 1. The error-correction threshold for the (89,45,17) quadratic residue code is set at 8.

Sᵢ=r(βⁱ)=c(βⁱ)+e(βⁱ)=e(βⁱ)=e₀+e₁β+ . . . +e₈₈β⁸⁸ (Equation 1)

where Sᵢ is a known syndrome, β is the primitive n^{th} root of unity in the field GF(2¹¹), and n is the code length.

The known syndromes are then used to calculate a plurality of unknown syndromes for (89,45,17) quadratic residue code (Step S110). Let Set I={i₁, i₂, . . . , iᵥ₊₁} and Set J={j₁, j₂, . . . , jᵥ₊₁} be subsets of {0, 1, . . . , n-1}, and let n be the code length. Matrices X(I) and X(J) of size (v+1)×v are defined as follows:

$$X ( I ) = [ \begin{matrix}{Z}_{1}^{{i}_{1}} & {Z}_{2}^{{i}_{1}} & ⋯ & {Z}_{v}^{{i}_{1}} \\ {Z}_{1}^{{i}_{2}} & {Z}_{2}^{{i}_{2}} & ⋯ & {Z}_{v}^{{i}_{2}} \\ ⋮ & ⋮ & ⋰ & ⋮ \\ {Z}_{1}^{{i}_{v}} & {Z}_{2}^{{i}_{v}} & ⋯ & {Z}_{v}^{{i}_{v}} \\ {Z}_{1}^{{i}_{v + 1}} & {Z}_{2}^{{i}_{v + 1}} & ⋯ & {Z}_{v}^{{i}_{v + 1}}\end{matrix} ] , \\ X ( J ) = [ \begin{matrix}{Z}_{1}^{{j}_{1}} & {Z}_{2}^{j} & ⋯ & {Z}_{v}^{j} \\ {Z}_{1}^{{j}_{2}} & {Z}_{2}^{{j}_{2}} & ⋯ & {Z}_{v}^{{j}_{2}} \\ ⋮ & ⋮ & ⋰ & ⋮ \\ {Z}_{1}^{{j}_{v}} & {Z}_{2}^{{j}_{v}} & ⋯ & {Z}_{v}^{{j}_{v}} \\ {Z}_{1}^{{j}_{v + 1}} & {Z}_{2}^{{j}_{v + 1}} & ⋯ & {Z}_{v}^{{j}_{v + 1}}\end{matrix} ]$$

One then defines matrix S(I, J)=X(I)X(J)^{T} and its theorem, where matrix X(J)^{T} is the transposed matrix of X(J), and S(I, J) is a matrix of size (v+1)×(v+1).

Theorem 1: Matrix S(I, J) has the following form:

$$S ( I , J ) = [ \begin{matrix}{S}_{{i}_{1} + {j}_{1}} & {S}_{{i}_{1} + {j}_{2}} & ⋯ & {S}_{{i}_{1} + {j}_{v + 1}} \\ {S}_{{i}_{2} + {j}_{1}} & {S}_{{i}_{2} + {j}_{2}} & ⋯ & {S}_{{i}_{2} + {j}_{v + 1}} \\ ⋮ & ⋮ & ⋰ & ⋮ \\ {S}_{{i}_{v} + {j}_{1}} & {S}_{{i}_{v} + {j}_{2}} & ⋯ & {S}_{{i}_{v} + {j}_{v + 1}} \\ {S}_{{i}_{v + 1} + {j}_{1}} & {S}_{{i}_{v + 1} + {j}_{2}} & ⋯ & {S}_{{i}_{v + 1} + {j}_{v + 1}}\end{matrix} ]$$

Where the subscript of S is the remainder after dividing by n, and n is the code length. Furthermore, the determinant of matrix S(I, J) is zero, i.e., det(S(I, J))=0.

Assuming that matrix S(I, J) contains a plurality of unknown syndromes, then det(S(I, J))=0 can be treated as an unknown syndrome equation, and the coefficient will be composed of the known syndromes. If matrix S(I, J) contains only one unknown syndrome Sᵣ^{(v)}, then Sᵣ^{(v)} can be derived using the following theorem, where Sᵣ^{(v)} is an unknown syndrome where the number of errors is assumed to be v.

Theorem 2: If matrix S(I, J) contains only one unknown syndrome Sᵣ^{(v)}, then Sᵣ^{(v)} can be expressed as a fraction. The value of this fraction is determined by successive division after expanding the determinants of two of the matrices contained in matrix S(I, J). If Sᵣ^{(v)} appears in row i and column j of matrix S(I, J), then

$${S}_{r}^{( v )} = \frac{det ( {Δ}_{0} )}{det ( Δ )} , ,$$

where Δ₀ denotes that the location of Sᵣ^{(v)} at row i and column j within matrix S(I, J) of size (v+1)×(v+1) is replaced by zero, and Δ is the sub-matrix of size v×v formed within S(I, J) by the elimination of row i and column j.

With the above theorem, the unknown syndromes for (89,45,17) quadratic residue code can be derived using the following equations:
Case 0: if no error is encountered, S₃⁽⁰⁾=0; S₁₃⁽⁰⁾=0
Case 1: S₃⁽¹⁾=S₁³; S₁₃⁽¹⁾=S₁¹³

In the following cases, v a) and b) define the sets I and J respectively. Theorems 1 and 2 can then be used to derive the two unknown syndromes S₃ and S₁₃.

### Case 2:

a) I₂={0, 1, 2}, J₂={0, 1, 87}

$$S ( {I}_{2} , {J}_{2} ) = [ \begin{matrix}{S}_{0} & {S}_{1} & {S}_{2} \\ {S}_{1} & {S}_{2} & {S}_{3}^{( 2 )} \\ {S}_{87} & {S}_{88} & {S}_{0}\end{matrix} ] .$$

S₃⁽²⁾=(S₁S₂S₈₈+S₄S₈₇)/(S₁+S₈₇)

b) I₂={0, 11, 88}, J₂={0, 2, 5}

$$S ( {I}_{2} , {J}_{2} ) = [ \begin{matrix}{S}_{0} & {S}_{11} & {S}_{88} \\ {S}_{2} & {S}_{13}^{( 2 )} & {S}_{1} \\ {S}_{5} & {S}_{16} & {S}_{4}\end{matrix} ] . \\ {S}_{13}^{( 2 )} = ( {S}_{2} {S}_{16} {S}_{88} + {S}_{2} {S}_{4} {S}_{11 +} {S}_{1} {S}_{5} {S}_{11} ) / ( {S}_{5} + {S}_{88} )$$

### Case 3:

a) I₃={0, 1, 87, 88}, J₃={0, 1, 2, 10}

$$S ( {I}_{3} , {J}_{3} ) = [ \begin{matrix}{S}_{0} & {S}_{1} & {S}_{87} & {S}_{88} \\ {S}_{1} & {S}_{2} & {S}_{88} & {S}_{0} \\ {S}_{2} & {S}_{3}^{( 3 )} & {S}_{0} & {S}_{1} \\ {S}_{10} & {S}_{11} & {S}_{8} & {S}_{9}\end{matrix} ] .$$

b) I₃={8, 9, 10, 13}, J₃={0, 8, 59, 71}

$$S ( {I}_{3} , {J}_{3} ) = [ \begin{matrix}{S}_{8} & {S}_{9} & {S}_{10} & {S}_{13}^{( 3 )} \\ {S}_{16} & {S}_{17} & {S}_{18} & {S}_{21} \\ {S}_{67} & {S}_{68} & {S}_{69} & {S}_{72} \\ {S}_{79} & {S}_{80} & {S}_{81} & {S}_{84}\end{matrix} ]$$

### Case 4:

a) I₄={1, 2, 3, 10, 32}, J₄={0, 7, 8, 77, 78}

b) I₄={0, 1, 2, 87, 88}, J₄={0, 1, 2, 3, 11}

### Case 5:

a) I₅¹={1, 16, 17, 20, 39, 57}, J₅¹={0, 33, 52, 68, 71, 72}

I₅²={0, 1, 8, 39, 49, 72}, J₅²={0, 1, 8, 39, 49, 84}

If there are 5 errors, then 1 set of (I, J) is not sufficient to define the unknown syndromes S₃⁽⁵⁾ for all situations where the number of errors is 5. Model testing using a computer has shown that 2 sets of (I, J) are needed to define the unknown syndromes S₃⁽⁵⁾ for all situations where the number of errors is 5.

b) I₅={0, 1, 2, 3, 4, 5}, J₅={0, 1, 2, 8, 87, 88}

If the unknown syndromes S₃⁽⁵⁾ obtained in a) are treated as known syndromes, then Theorems 1 and 2 can be used to calculate the two unknown syndromes S₁₃⁽⁵⁾.

### Case 6:

a) I₆¹={1, 2, 3, 4, 9, 71, 87}, J₆¹={0, 1, 2, 7, 8, 86, 87}

I₆²={1, 2, 3, 4, 5, 11, 87}, J₆²={0, 1, 5, 6, 7, 86, 87}

I₆³={1, 2, 3, 4, 9, 87, 88}, J₆³={0, 1, 2, 7, 8, 46, 86}

If there are 6 errors, then 1 set of (I, J) is not sufficient to define the unknown syndromes S₃⁽⁶⁾ for all situations where the number of errors is 6. Model testing using a computer has shown that 3 sets of (I, J) are needed to define the unknown syndromes for all situations where the number of errors is 6. For all three sets of (I, J), the determinant expansion takes the form of a non-linear S₃⁽⁶⁾ polynomial; using Theorem 2, it can be determined that these determinants are equal to zero. In other words, the three polynomials have similar linear factors. Therefore, if the linear factors of these three polynomials can be determined, it will then be possible to define a single value for S₃⁽⁶⁾. In b), S₃⁽⁶⁾ can be treated as a known value.

b) I₆¹={0, 1, 2, 3, 4, 5, 6}, J₆¹={0, 1, 2, 3, 7, 87, 88}

If the unknown syndromes S₃⁽⁶⁾ obtained in a) are treated as known syndromes, then Theorems 1 and 2 can be used to calculate the two unknown syndromes S₁₃⁽⁶⁾.

### Case 7:

a) I₇¹={2, 3, 4, 6, 7, 8, 14, 20}, J₇¹={0, 2, 4, 14, 65, 85, 86, 87}, I₇²={1, 2, 3, 4, 6, 8, 14, 87}, J₇²={0, 2, 3, 4, 6, 8, 86, 87}, I₇³={1, 2, 3, 4, 9, 10, 71, 87}, J₇^{3={0, 1, 2, 7, 8, 46, 86, 87}}

The situation here is similar to the situation with 6 errors. Three sets of (I, J) are needed to define the unknown syndromes S₃⁽⁷⁾ for all situations where the number of errors is 7. Once the unknown syndromes S₃⁽⁷⁾ have been defined, then the unknown syndromes S₃⁽⁷⁾ in b) can be treated as a known value.

b) I₇¹={0, 1, 3, 6, 8, 17, 40, 84}, J₇¹={0, 4, 5, 6, 8, 17, 39, 47}, I₇²={0, 1, 3, 6, 8, 17, 40, 88}, J₇²={0, 4, 5, 6, 8, 17, 47, 88}, I₇³={1, 2, 4, 7, 9, 18, 42, 87}, J₇³={0, 4, 5, 7, 38, 46, 83, 87}

If, after expansion, the determinants of the three sets of (I, J) are treated as zero, then three linear equations can be derived for S₁₃⁽⁷⁾. A single value can be determined for S₁₃⁽⁷⁾ using any one of these equations.

### Case 8:

a) I₈¹={1, 2, 3, 6, 17, 20, 45, 84, 87}, J₈¹={0, 3, 4, 5, 8, 19, 22, 47, 86}, I₈²={1, 3, 5, 6, 7, 11, 17, 39, 84}, J₈²={0, 1, 3, 5, 11, 17, 39, 84, 86}, I₈³={1, 2, 3, 4, 5, 6, 9, 20, 87}, J₈³={0, 1, 2, 3, 5, 19, 44, 86, 87}, I₈⁴={6, 7, 8, 9, 40, 53, 56, 57, 72}, J₈⁴={0, 15, 16, 38, 39, 40, 41, 72, 81}

The situation here is similar to the situation with 7 errors. Four sets of (I, J) are needed to define the unknown syndromes S₃⁽⁸⁾ for all situations where the number of errors is 8. Once the unknown syndromes S₃⁽⁸⁾ have been defined, then the unknown syndromes S₃⁽⁸⁾ in b) can be treated as a known value.

b) I₈¹={2, 6, 7, 8, 9, 18, 53, 85, 87}, J₈¹={0, 2, 3, 4, 14, 16, 38, 82, 83}, I₈²={0, 1, 2, 3, 4, 5, 6, 20, 87}, J₈²={0, 1, 2, 3, 4, 5, 8, 44, 87}, I₈³={1, 2, 3, 4, 5, 6, 9, 20, 45}J₈³={0, 1, 2, 3, 4, 5, 19, 44, 86}

If, after expansion, the determinants of the three sets of (I, J) are treated as zero, then three linear equations can be derived for S₁₃⁽⁸⁾. A single value can be determined for S₁₃⁽³⁾ using any one of these equations.

Using a plurality of known syndromes and a plurality of unknown syndromes that are treated as known, the inverse-free Berlekamp-Massey algorithm can be used to calculate the error polynomial (Step S120). In this step, a plurality of known syndromes and a plurality of unknown syndromes are used as known input values, and the inverse-free Berlekamp-Massey algorithm (which is able to derive the cyclic code error polynomial in an efficient manner) is used to calculate the error polynomial. The steps in the inverse-free Berlekamp-Massey algorithm are shown below:
Step 1) The initial values are set as k=1, r⁽⁰⁾=1, C⁽⁰⁾(x)=1, A⁽⁰⁾(x)=1 and l⁽⁰⁾=1
Step 2) Calculate the difference

$${Δ}^{( k )} = {\sum }_{j = 1}^{{l}^{( k - 1 )}} {c}_{j - 1}^{( k - 1 )} {S}_{k - j + 1}$$

Step 3) Calculate the error polynomial

C^{(k)}(x)=r^{(k-1)}C^{(k-1)}(x)−Δ^{(k)}A^{(k-1)}(x)·x
Step 4) Substitution of auxiliary variables A^{(k)}(x), A^{(k)}, 1^{(k)} and r^{(k)}

$${A}^{( k )} ( x ) = \{ \begin{matrix} x \cdot {A}^{( k - 1 )} ( x ) , if {Δ}^{( k )} = 0 or 2 {l}^{( k - 1 )} > k - 1 \\ {C}^{( k - 1 )} ( x ) , if {Δ}^{( k )} \neq 0 or 2 {l}^{( k - 1 )} \leq k - 1\end{matrix} \\ {l}^{( k )} ( x ) = \{ \begin{matrix} {l}^{( k - 1 )} , if {Δ}^{( k )} = 0 or 2 {l}^{( k - 1 )} > k - 1 \\ k - {l}^{( k - 1 )} , if {Δ}^{( k )} \neq 0 or 2 {l}^{( k - 1 )} \leq k - 1\end{matrix} \\ {r}^{( k )} ( x ) = \{ \begin{matrix} {r}^{( k - 1 )} , if {Δ}^{( k )} = 0 or 2 {l}^{( k - 1 )} > k - 1 \\ {Δ}^{( k )} , if {Δ}^{( k )} \neq 0 or 2 {l}^{( k - 1 )} \leq k - 1\end{matrix}$$

Step 5) Move on to the next step: k=k+1. If k≦2t, then go back to Step 2), otherwise the process is completed.

C^{(k)}(x) denotes the error polynomial at the k^{th} stage, Δ^{(k)} if the difference calculated from known syndrome Sₖ, and A^{(k)}(x), A^{(k)}, l^{(k)} and r^{(k)} are auxiliary variables for determining the error polynomial at the k^{th} stage.

One then moves on to determine whether the highest degree of the error polynomial conforms to the number of errors (Step S130). In this step, the equation deg(σ(x))=v is used to determine whether the highest degree of the polynomial is the same as the number of errors; deg(σ(x)) is the highest degree of the error polynomial, and, as noted above, v is the number of errors.

If it is determined that the highest degree of the error polynomial is the same as the number of errors, then one moves on to calculate the root and root number of the error polynomial (Step S140). In this step, the error polynomial root and root number are calculated using the error polynomial and the Chien search algorithm (the Chien search algorithm is used for finding roots of polynomials over finite fields; it produces better results than other algorithms when finding roots of error polynomials).

If it is determined that the highest degree of the error polynomial is not the same as the number of errors, then a specified value is added to the number of errors and a determination is made as to whether the number of errors now exceeds the error-correction threshold (Step S150). In this step, the specified value is set at 1, and the error-correction threshold for the (89,45,17) quadratic residue code is set at 8. When the number of errors exceeds the error-correction threshold, this implies that no further adjustment of the digital signal can be performed, and the algorithm is terminated. If the number of errors has not yet exceeded the error-correction threshold, then one goes back to using a plurality of known syndromes to calculate a plurality of unknown syndromes for the (89,45,17) quadratic residue code (Step S110).

The next step is to determine whether the root number obtained for the error polynomial matches the number of errors (Step S160). First, the root number is calculated; then, a determination is made as to whether the number that has been obtained matches the number of errors. The formula used in this stage is u=v, where u is the root number, and v is the number of errors.

If it is determined that the root number matches the number of errors, then the next step is to identify the error locations for the error polynomial, and to adjust the values of the error locations (Step S170). In this step, the error polynomial is used to determine the locations where errors have occurred in the digital (input) signal; the values at these locations are then adjusted to obtain correct values.

If, on the other hand, it is determined that the root number does not match the number of errors, then one goes back to adding a specified value to the number of errors and determining whether the number of errors now exceeds the error-correction threshold (Step S150).

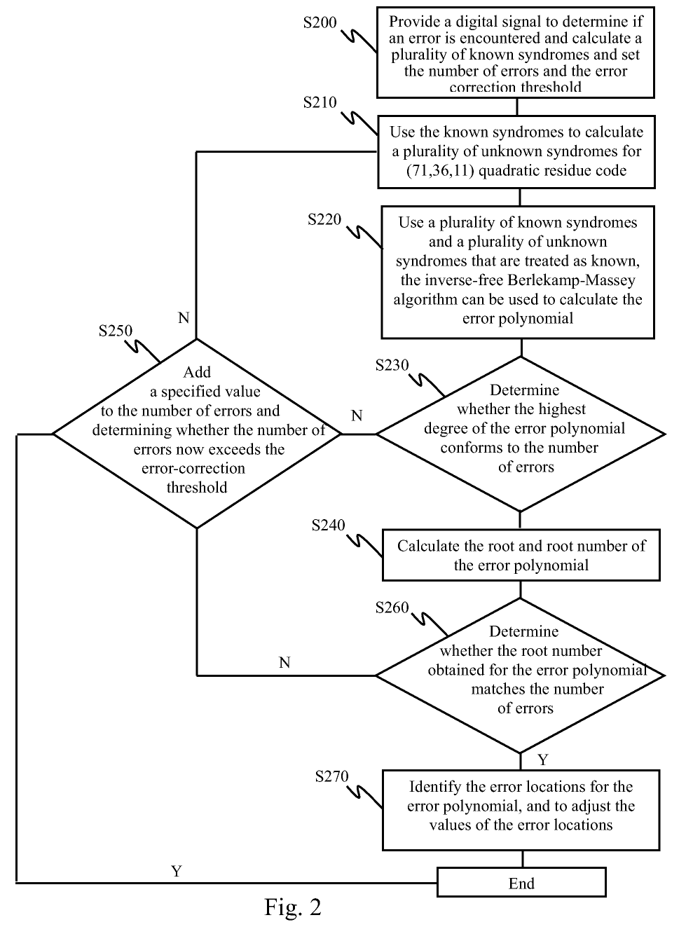

A second embodiment of the quadratic residue code decoding algorithm of the present invention, in the decoding of the (71,36,11) quadratic residue code, is illustrated in FIG. 2. The decoding process comprises the following steps:

A digital signal is provided, and used to calculate a plurality of known syndromes and set the number of errors if error is encountered and the error correction threshold (Step S200). During this step, Equation 2 is used to derive a plurality of known syndromes from the digital signal. It is assumed that the number of errors is v; this value is initially set at 1. The error-correction threshold for the (71,36,11) quadratic residue code is set at 5.

Sᵢ=r(βⁱ)=e(βⁱ)=e₀+e₁β¹+ . . . +eₙ₋₁βⁿ⁻¹ (Equation 2)

where Sᵢ is a known syndrome, and β is the primitive n^{th} root of unity in the field GF(2³⁵)

The known syndromes are then used to calculate a plurality of unknown syndromes for the (71,36,11) quadratic residue code (Step S210). The method used to calculate the unknown syndromes S₇ for the (71,36,11) quadratic residue code is described below.
Case 0: S₇⁽⁰⁾=0
Case 1: S₇⁽¹⁾=S₁⁷
Case 2: I₂={0, 1, 2}, J₂={0, 1, 5}

$$S ( {I}_{2} , {J}_{2} ) = [ \begin{matrix}{S}_{0} & {S}_{1} & {S}_{2} \\ {S}_{1} & {S}_{2} & {S}_{3} \\ {S}_{5} & {S}_{6} & {S}_{7}^{( 2 )}\end{matrix} ] . \\ {S}_{7}^{( 2 )} = ( {S}_{1} {S}_{6} + {S}_{2} {S}_{5} ) + ( {S}_{3} {S}_{5} / {S}_{1} )$$

Case 3: I₃={0, 1, 2, 3}, J₃={0, 1, 2, 4}

$$S ( {I}_{3} , {J}_{3} ) = [ \begin{matrix}{S}_{0} & {S}_{1} & {S}_{2} & {S}_{3} \\ {S}_{1} & {S}_{2} & {S}_{3} & {S}_{4} \\ {S}_{2} & {S}_{3} & {S}_{4} & {S}_{5} \\ {S}_{4} & {S}_{5} & {S}_{7}^{( 3 )} & {S}_{8}\end{matrix} ] .$$

Case 4: I₄={0, 1, 2, 4, 7}, J₄={0, 1, 2, 8, 36}
Case 5: I₅¹={0, 1, 2, 4, 7, 24 }, J₅¹={0, 1, 3, 5, 8, 36}

I₅²={3, 4, 5, 12, 15, 45}, J₅²={0, 3, 4, 15,33, 45}

If there are 5 errors, then 1 set of (I, J) is not sufficient to define the unknown syndromes for S₇⁽⁵⁾ for all situations where the number of errors is 5. If, after expansion, the determinants of the two matrices S(I₅¹, J₅¹) and S(I₅², J₅²) are zero, then the following cubic equations can be derived for the two unknown syndromes S₇⁽⁵⁾: f₁(S₇⁽⁵⁾)=0, and g₁(S₇⁽⁵⁾)=0, where the coefficient is formed from known syndromes. Let F₁(S₇⁽⁵⁾)=gcd(f₁(S₇⁽⁵⁾),g₁(S₇⁽⁵⁾)), then F₁(S₇⁽⁵⁾) is a quadratic polynomial in all cases where the number of errors is 5, and F₁(S₇⁽⁵⁾)=0 can be used to derive the unknown syndromes S₇⁽⁵⁾.

Using a plurality of known syndromes and a plurality of unknown syndromes that are treated as known, the inverse-free Berlekamp-Massey algorithm can be used to calculate the error polynomial (Step S220). In this step, a plurality of known syndromes and a plurality of unknown syndromes are used as known input values, and the inverse-free Berlekamp-Massey algorithm (which is able to derive the cyclic code error polynomial in an efficient manner) is used to calculate the error polynomial. The steps in the inverse-free Berlekamp-Massey algorithm are the same as those outlined in Step S120 of the (89,45,17) quadratic residue code embodiment.

One then moves on to determine whether the highest degree of the error polynomial matches the number of errors (Step S230). In this step, the equation deg(σ(x))=v is used to determine whether the highest degree of the polynomial matches the number of errors; deg(σ(x)) is the highest degree of the error polynomial, and, as noted above, v is the number of errors.

If it is determined that the highest degree of the error polynomial is the same as the number of errors, then one moves on to calculate the root and root number of the error polynomial (Step S240). In this step, the error polynomial root and root number are calculated using the error polynomial and the Chien search algorithm (the Chien search algorithm is used for finding roots of polynomials over finite fields; it produces better results than other algorithms when finding roots of error polynomials).

If it is determined that the highest degree of the error polynomial is not the same as the number of errors, then a specified value is added to the number of errors and a determination is made as to whether the number of errors now exceeds the error-correction threshold (Step S250). In this step, the specified value is set at 1, and the error-correction threshold for the (71,36,11) quadratic residue code is set at 5. When the number of errors exceeds the error-correction threshold, this implies that no further adjustment of the digital signal can be performed, and the algorithm is terminated. If the number of errors has not yet exceeded the error-correction threshold, then one goes back to using a plurality of known syndromes to calculate a plurality of unknown syndromes for the (71,36,11) quadratic residue code (Step S210).

The next step is to determine whether the root number obtained for the error polynomial matches the number of errors (Step S260). First, the root number is calculated; then, a determination is made as to whether the number that has been obtained matches the number of errors. The formula used in this stage is u=v, where u is the root number, and v is the number of errors.

If it is determined that the root number matches the number of errors, then the next step is to identify the error locations for the error polynomial, and to adjust the values of the error locations (Step S270). In this step, the error polynomial is used to determine the locations where errors have occurred in the digital (input) signal; the values at these locations are then adjusted to obtain correct values.

If, on the other hand, it is determined that the root number does not match the number of errors, then one goes back to adding a specified value to the number of errors and determining whether the number of errors now exceeds the error-correction threshold (Step S250).

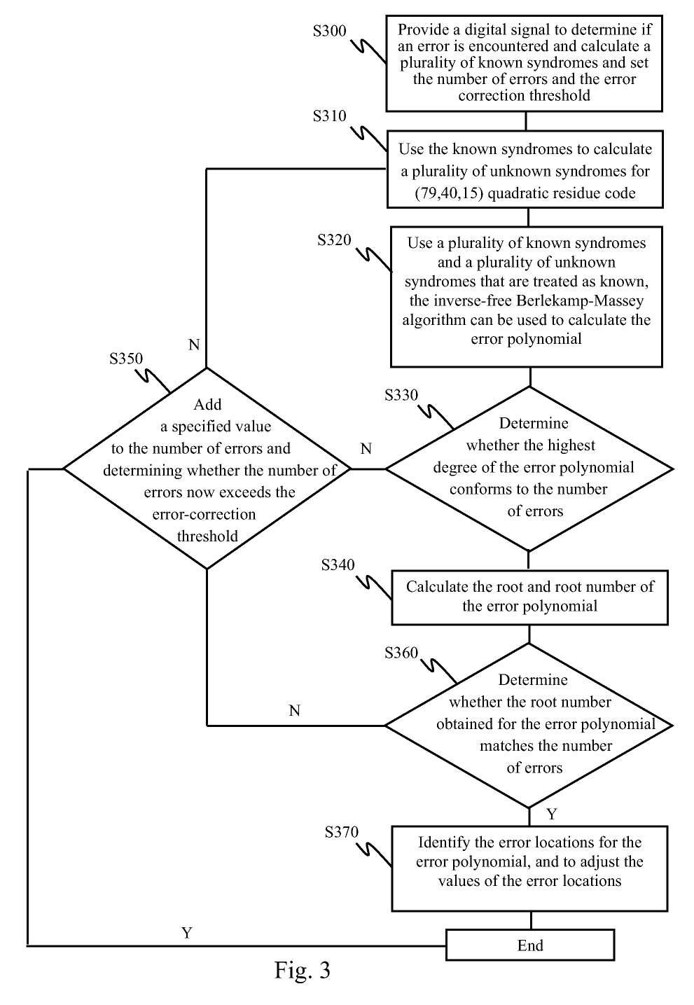

A third embodiment of the quadratic residue code decoding algorithm of the present invention, in the decoding of the (79,40,15) quadratic residue code, is illustrated in FIG. 3. The decoding process comprises the following steps:

A digital signal is provided, and used to calculate a plurality of known syndromes and set the number of errors if error is encountered and the error correction threshold (Step S300). During this step, Equation 3 is used to derive a plurality of known syndromes from the digital signal. It is assumed that the number of errors is v; this value is initially set at 1. The error-correction threshold for the (79,40,15) quadratic residue code is set at 7.

Sᵢ=r(βⁱ)=e(βⁱ)=e₀+e₁β¹+ . . . +eₙ₋₁βⁿ⁻¹ (Equation 3)

where Sᵢ is a known syndrome, and β is the primitive n^{th} root of unity in the field GF(2³⁹).

The known syndromes are then used to calculate a plurality of unknown syndromes for the (79,40,15) quadratic residue code (Step 310). The method used to calculate the unknown syndromes S₃ for the (79,40,15) quadratic residue code is described below.
Case 0: S₃⁽⁰⁾=0
Case 1: S₃⁽¹⁾=S₁³
Case 2: I₂={0, 1, 2}, J₂={0, 1, 8}

$$S ( {I}_{2} , {J}_{2} ) = [ \begin{matrix}{S}_{0} & {S}_{1} & {S}_{2} \\ {S}_{1} & {S}_{2} & {S}_{3}^{( 2 )} \\ {S}_{8} & {S}_{9} & {S}_{10}\end{matrix} ] . \\ {S}_{3}^{( 2 )} = {S}_{1} {S}_{2} + ( {S}_{1} {S}_{10} + {S}_{2} {S}_{9} / {S}_{8} )$$

Case 3: I₃={0, 1, 2, 3}, J₃={0, 8, 18, 19}

$$S ( {I}_{3} , {J}_{3} ) = [ \begin{matrix}{S}_{0} & {S}_{1} & {S}_{2} & {S}_{3}^{( 3 )} \\ {S}_{8} & {S}_{9} & {S}_{10} & {S}_{11} \\ {S}_{18} & {S}_{19} & {S}_{20} & {S}_{21} \\ {S}_{19} & {S}_{20} & {S}_{21} & {S}_{22}\end{matrix} ] .$$

Case 4: I₄={0,1, 2, 3, 13}, J₄={0, 8, 18, 19, 49}
Case 5: I₅¹={2, 3, 4, 19, 25, 73}, J₅¹={0, 6, 7, 17, 19, 48}
Case 6: I₆¹={1, 2, 3, 4, 5, 64, 72}, J₆¹={0, 1, 8, 17, 18, 19, 20}

I₆²={0, 1, 2, 3, 16, 22, 42}, J₆²={0, 2, 3, 9, 10, 20, 22}

If there are 6 errors, then 1 set of (I, J) is not sufficient to define the unknown syndromes S₃⁽⁶⁾ for all situations where the number of errors is 6. For two sets of (I, J), the determinant expansion takes the form of a non-linear S₃⁽⁶⁾ polynomial; using Theorem 2, as described in the (89,45,17) quadratic residue code embodiment, it can be determined that these determinants are equal to zero. In other words, the two polynomials have linear factors that are at least similar. Euclid's algorithm can then be used to find the highest common factor of the two polynomials. Computer modeling has shown that the two sets can be used to derive a linear factor which can be used to define a single value for S₃⁽⁶⁾ for all cases where there are 6 errors.
Case 7: I₇¹={0, 1, 2, 3, 4, 5, 64, 72}, J₇¹={0, 1, 8, 16, 17, 18, 19, 20}, I₇²={0 1, 2, 3, 4, 16, 18, 24}, J₇²={0, 1, 2, 8, 16, 18, 20, 22}

The situation here is similar to the situation with 6 errors. Once the determinants of S(I₇¹, J₇¹) and S(I₇², J₇²) have been expanded, one obtains the following polynomials for S₃⁽⁷⁾: f₂(S₃⁽⁷⁾), an 83-dimensional polynomial, and g₂(S₃⁽⁷⁾), a 153-dimensional polynomial. Euclid's algorithm can then be used to find the highest common factor of the two polynomials: F₂(S₃⁽⁷⁾)=gcd(f₂(S₃⁽⁷⁾), g₂(S₃⁽⁷⁾)). The code obtained from computer modeling shows that the F₂(S₃⁽⁷⁾) polynomials are all linear polynomials. Using Theorem 1 from the (89,45,17) quadratic residue code embodiment, one can determine that f₂(S₃⁽⁷⁾)=0 and g₂(S₃⁽⁷⁾)=0, so F₂(S₃⁽⁷⁾) is also 0. It is therefore also possible to derive a single definition for all primitive unknown syndromes S₃⁽⁷⁾ where the number of errors is 7.

Using a plurality of known syndromes and a plurality of unknown syndromes that are treated as known, the inverse-free Berlekamp-Massey algorithm can be used to calculate the error polynomial (Step S320). In this step, a plurality of known syndromes and a plurality of unknown syndromes are used as known input values, and the inverse-free Berlekamp-Massey algorithm (which is able to derive the cyclic code error polynomial in an efficient manner) is used to calculate the error polynomial. The steps in the inverse-free Berlekamp-Massey algorithm are the same as those outlined in Step S120 of the (89,45,17) quadratic residue code embodiment.

One then moves on to determine whether the highest degree of the error polynomial matches the number of errors (Step S330). In this step, the equation deg(σ(x))=v is used to determine whether the highest degree of the polynomial matches the number of errors; deg(σ(x)) is the highest degree of the error polynomial, and, as noted above, v is the number of errors.

If it is determined that the highest degree of the error polynomial is the same as the number of errors, then one moves on to calculate the root and root number of the error polynomial (Step S340). In this step, the error polynomial root and root number are calculated using the error polynomial and the Chien search algorithm (the Chien search algorithm is used for finding roots of polynomials over finite fields; it produces better results than other algorithms when finding roots of error polynomials).

If it is determined that the highest degree of the error polynomial is not the same as the number of errors, then a specified value is added to the number of errors and a determination is made as to whether the number of errors now exceeds the error-correction threshold (Step S350). In this step, the specified value is set at 1, and the error-correction threshold for the (79,40,15) quadratic residue code is set at 7. When the number of errors exceeds the error-correction threshold, this implies that no further adjustment of the digital signal can be performed, and the algorithm is terminated. If the number of errors has not yet exceeded the error-correction threshold, then one goes back to using a plurality of known syndromes to calculate a plurality of unknown syndromes for the (79,40,15) quadratic residue code (Step S310).

The next step is to determine whether the root number obtained for the error polynomial is in conformity with the number of errors (Step S360). First, the root number is calculated; then, a determination is made as to whether the number that has been obtained matches the number of errors. The formula used in this stage is u=v, where u is the root number, and v is the number of errors.

If it is determined that the root number matches the number of errors, then the next step is to identify the error locations for the error polynomial, and to adjust the values of the error locations (Step S370). In this step, the error polynomial is used to determine the locations where errors have occurred in the digital (input) signal; the values at these locations are then adjusted to obtain correct values.

If, on the other hand, it is determined that the root number does not match the number of errors, then one goes back to adding a specified value to the number of errors and determining whether the number of errors now exceeds the error-correction threshold (Step S350).

The preferred embodiments of the present invention have been disclosed in the examples. However the examples should not be construed as a limitation on the actual applicable scope of the invention, and as such, all modifications and alterations without departing from the spirits of the invention and appended claims shall remain within the protected scope and claims of the invention.

What is claimed is:

1. A quadratic residue code decoding algorithm comprising the steps of:
providing a digital signal to determine if an error is encountered and calculate a plurality of known syndromes and setting a number of errors and an error correction threshold;
using said known syndromes to calculate a plurality of unknown syndromes;
treating said unknown syndromes as known, and using said known syndromes and said unknown syndromes to calculate an error polynomial;
determining whether the highest dimension of said error polynomial matches said number of errors;
if said highest dimension of said error polynomial matches said number of errors, calculating at least one root and at least one root number for said error polynomial;
if said highest dimension of error polynomial does not match said number of errors, adding a specified value to said number of errors, and determining whether said number of errors now exceeds said error correction threshold; if it is determined that said number of errors does not exceed said error correction threshold, then going back to the step of using said known syndromes to calculate a plurality of unknown syndromes;
determining whether said root number of said error polynomial matches said number of errors;
if said root number of said error polynomial matches said number of errors, determining at least one error location for said error polynomial, and adjusting the digital value corresponding to said error location; and
if said root number of said error polynomial does not match said number of errors, going back to the step of adding a specified value to said number of errors, and determining whether said number of errors now exceeds said error correction threshold.

2. The quadratic residue code decoding algorithm as claimed in claim 1 wherein said quadratic residue code decoding algorithm is applicable to all quadratic residue codes.

3. The quadratic residue code decoding algorithm as claimed in claim 1 wherein said quadratic residue code is applicable to the (89,45,17) quadratic residue code.

4. The quadratic residue code decoding algorithm of claim 1 wherein said number errors is initially set at 1, and said specified value is set at 1.

5. The quadratic residue code decoding algorithm as claimed in claim 1, wherein said unknown syndromes are treated as known and said known syndromes and said unknown syndromes are used to calculate said error polynomial, wherein said known syndromes and said unknown syndromes are entered into said error polynomial as known values, and the inverse-free Berlekamp-Massey algorithm is used to calculate said error polynomial.

6. The quadratic residue code decoding algorithm as claimed in claim 1, wherein the Chien search algorithm is used to calculate at least one root and at least one root number of said error polynomial.
